(19) United States
(12) Patent Application Publication
(10) Pub. No.: US 2010/0258232 A1
(43) Pub. Date: Oct. 14, 2010

(54) APPARATUS AND METHOD FOR SECURING SOLID-STATE LIGHT SOURCE

(75) Inventor: CHIH-MING LAI, Chu-Nan (TW)

Correspondence Address: Altis Law Group, Inc.;ATTN: Steven Reiss, 288 SOUTH MAYO AVENUE, CITY OF INDUSTRY, CA, 91789, US

(73) Assignee: FOXSEMICON INTEGRATED TECHNOLOGY, INC., Chu-Nan (TW)

(21) Appl. No.: 12/616,866

(22) Filed: Nov. 12, 2009

(30) Foreign Application Priority Data
Apr. 10, 2009 (CN) 200910301465.X

(51) Int. Cl. B32B 38/00; H01L 31/14

(52) U.S. Cl. 156/64; 250/552

(57) ABSTRACT

An exemplary apparatus for securing a solid-state light source on a base includes a laser emitter, an adjustment member, a photo sensor, and a drive member. The solid-state light source has a light source surface and a central axis. The base has a supporting surface, which includes plane regions. The laser emitter is configured for generating a laser beam to an imaginary reference surface. The adjustment member is configured for adjusting an orientation of the base to have a selected plane coaxial with the imaginary reference surface and reflect the laser beam. The photo sensor is configured for sensing an intensity of the laser beam. The drive member is configured for moving the solid-state light source toward until the light source surface of the solid-state light source is attached to the selected plane region immediately with the central axis thereof being coaxial with the imaginary normal.

### BACKGROUND

1. Technical Field

The disclosure generally relates to apparatuses for automated assembly of products, and particularly to an apparatus for securing a solid-state light source on a surface of a base.

2. Description of Related Art

Nowadays, light emitting diodes (LEDs) are extensively used as light sources for illumination devices due to their high luminous efficiency, low power consumption and long lifespan. A single LED generally has a limited radiating range. To achieve a large radiating range, a plurality of LEDs may be employed and secured on a single base. Such base may also used to dissipate heat from the LEDs, particularly if the base is made of good heat conductive material. In operation of the LEDs, heat from the LEDs can be dissipated to ambient air via the base.

The LEDs are preferably intimately joined to the base, otherwise the heat may not be transferred to the base efficiently. If heat accumulates on the LEDs and the temperature of the LEDs becomes too high, the light intensities of the LEDs may gradually attenuate and the working lifetimes of the LEDs are liable to be shortened.

Therefore, what is needed is an apparatus and a method for securing an LED on a base which overcome the described limitations.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views, and all the views are schematic.

FIG. 1 is a side view of an apparatus, according to an exemplary embodiment.

FIG. 2 is an isometric view of an LED chip operated on by the apparatus of FIG. 1.

FIG. 3 is an isometric view of a base, the LED chip of FIG. 2 being secured on the base by the apparatus.

FIG. 4 illustrates operation of the apparatus of FIG. 1, wherein the apparatus clamps the base of FIG. 3 and thereby a laser beam is reflected by a surface of the base.

FIG. 5 is similar to FIG. 4, but further showing the LED chip of FIG. 2 being secured on the base.

FIG. 6 is a flowchart of a method for securing the LED chip of FIG. 2 on the base of FIG. 3 using the apparatus of FIG. 1.

FIG. 7 is an isometric view of the base of FIG. 3 after a plurality of LED chips of FIG. 2 have been secured thereon using the method of FIG. 6.

### DETAILED DESCRIPTION

Embodiments will now be described in detail below, with reference to the drawings.

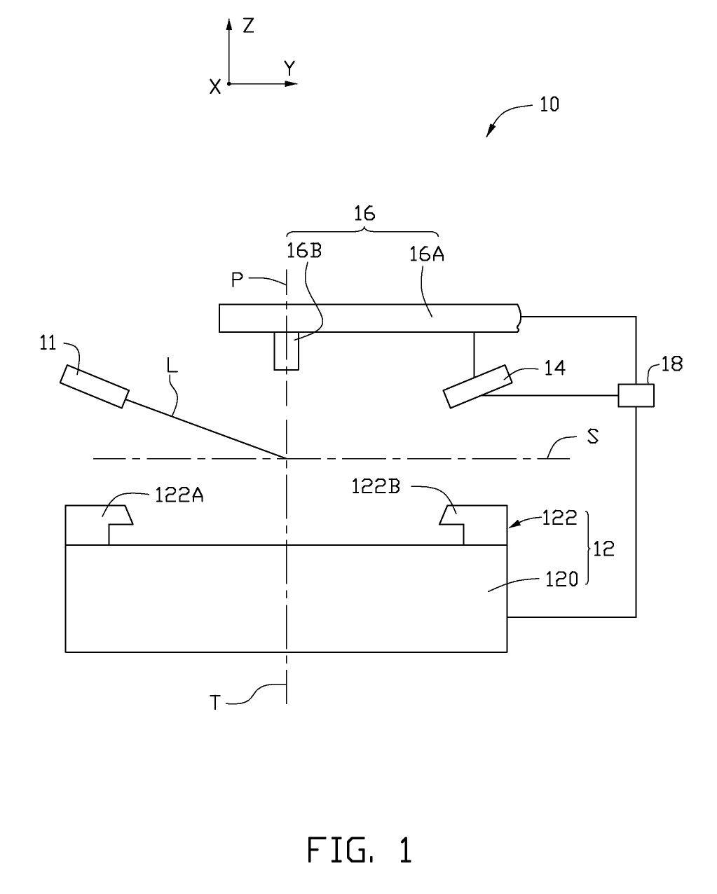

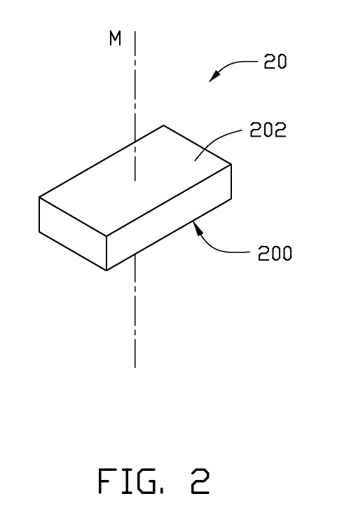

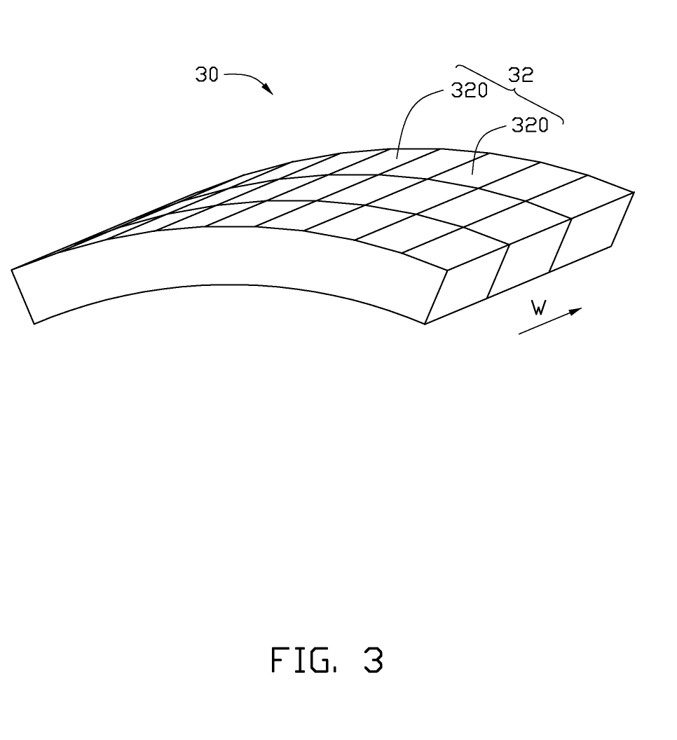

Referring to FIGS. 1-3, an apparatus 10 according to an exemplary embodiment is used to secure a solid-state light source 20 on a base 30. The solid-state light source 20 may for example be an LED or an LED chip. In the embodiment of FIG. 2, the solid-state light source 20 is an LED chip. The solid-state light source 20 has a first surface 200 and a second surface 202 at two opposite sides thereof. The solid-state light source 20 also has a central axis M perpendicular to the first surface 200. As shown in FIG. 3, the base 30 may for example be arc-shaped, with a generally arc-shaped supporting surface 32. The supporting surface 32 is thus a convex surface, and can be considered to be approximately the product of an arc generatrix extending along a direction W. The supporting surface 32 may be comprised of a plurality of substantially plane regions 320. In particular, the supporting surface 32 may be divided into a regular m×n array of substantially plane regions 320. The apparatus 10 includes a laser emitter 11, an adjustment member 12, a photo sensor 14, and a drive member 16.

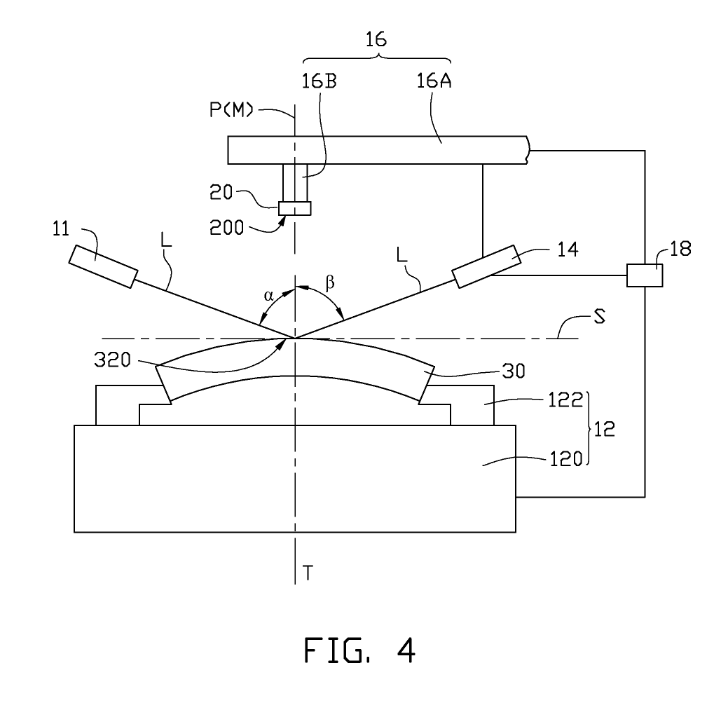

As shown in FIG. 1, an imaginary reference surface S is defined in an XY-plane of a Cartesian axis system. The imaginary reference surface S defines an imaginary normal T. The laser emitter 11 and the photo sensor 14 are arranged at two sides of the imaginary normal T. The laser emitter 11 is used to emit a laser beam L to the imaginary reference surface S. Referring also to FIG. 4, the photo sensor 14 is used to receive the laser beam L reflected by one of the plane regions 320.

The adjustment member 12 is used to hold and adjust an orientation of the base 30, such that one of the plane regions 320 can reflect the laser beam L to the photo sensor 14. Typically, the adjustment member 12 includes a movable base 120, and a clamp 122. In one embodiment, the movable base 120 may move horizontally relative to the imaginary reference surface S in X-axis directions and Y-axis directions of the XY-plane. In further or alternative embodiments, the movable base 120 can rotate in the XY-plane. In other alternative embodiments, the movable plate 131 may also move in vertical directions relative to the XY-plane, i.e., in Z-axis directions. The clamp 122 is mechanically coupled to the movable base 120, and may for example include a left jaw 122A and a right jaw 122B. In a typical application, the base 30 may be disposed on the movable base 120 between the left and right jaws 122A, 122B. By moving the left and right jaws 122A, 122B toward one another, the left and right jaws 122A, 122B clamp the base 30 at two opposite sides thereof. Generally, the left and right jaws 122A, 122B may each be moved by a conventional actuator (not shown), for example, an electric motor, a pneumatic cylinder, a hydraulic cylinder, or another suitable actuator. After the solid-state light source 20 is secured on the base 30, the left and right jaws 122A, 122B may be moved away from one another to disengage from the base 30.

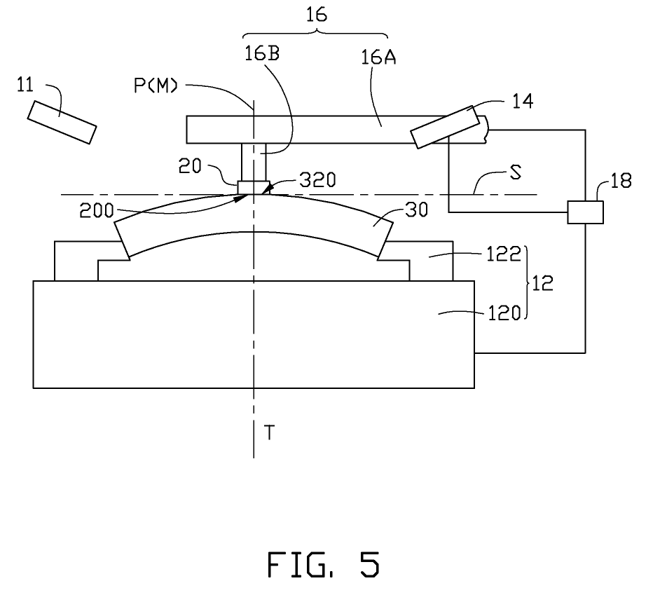

Referring also to FIG. 5, the drive member 16 is used to hold and move the solid-state light source 20. In the illustrated embodiment, the drive member 16 includes an arm 16A and a pick up element 16B. The arm 16A may be moved by a conventional actuator (not shown) along a processing path P. The actuator may for example be an electric motor, a pneumatic cylinder, a hydraulic cylinder, or another suitable actuator. The pick up element 16B is attached to the arm 16A, and is thereby moved by the arm 16A along the processing path P. The processing path P may for example be coaxial with the imaginary normal T. The pick up element 16B may have a structure similar to that of the clamp 122, and is for clamping and holding the solid-state light source 20. Alternatively, the pick up element 16B may be a vacuum pick up device with a suction cup, which is connected to a vacuum pump (not shown). In a typical application of the vacuum pick up device, after the suction cup is positioned on the second surface 202 of the solid-state light source 20, the vacuum pump is used to provide a pressure below atmospheric pressure in the suction cup. As a result, the solid-state light source 20 is attached to the suction cup by the provision of the vacuum pressure in the suction cup. With the solid-state light source 20 attached to the suction cup, the arm 16A moves the solid-state light source 20 towards the base 30. The solid-state light source 20 is then attached to one of the plane regions 320 of the base 30.

The apparatus 10 may further include a control module 18 for selecting a most suitable plane region 320 among the plane regions 320. The selected plane region 320 may for example be the smoothest plane region 320 among all the plane regions 320. Thus, the solid-state light source 20 can be intimately secured on the selected plane region 320. The control module 18 may be electrically connected to the photo sensor 14. Thereby, the control module 18 may select the most suitable plane region 320 according to the intensity of the laser beam L sensed by the photo sensor 14. Generally, the photo sensor 14 senses a largest light intensity of the laser beam L when the laser beam L is reflected by the smoothest plane region 320.

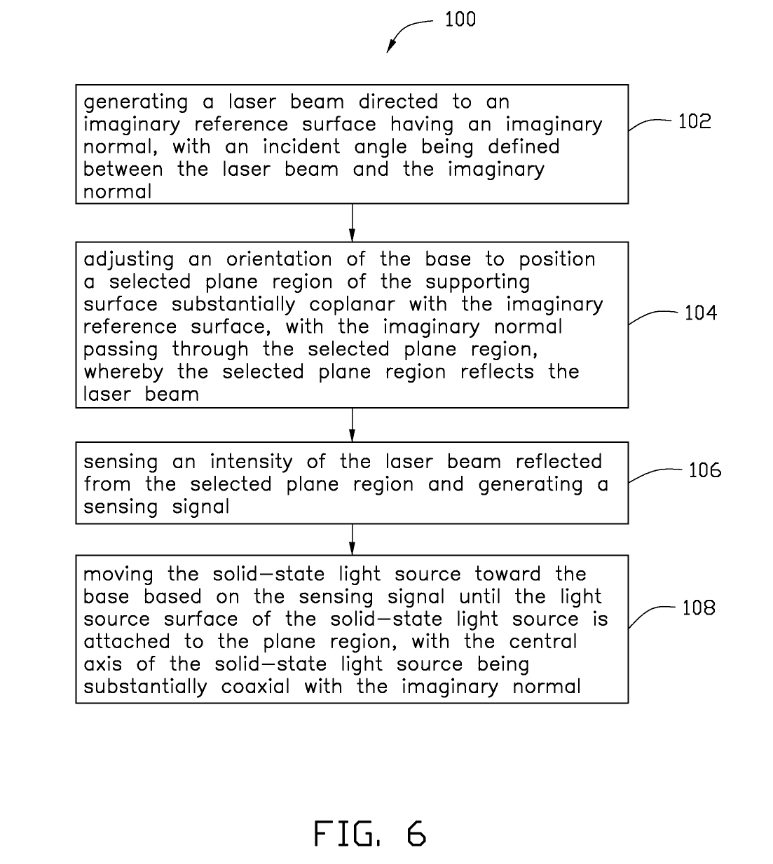

Referring to FIG. 6, a method 100 for securing the solid-state light source 20 on the base 30 in accordance with an exemplary embodiment is summarized. The apparatus 10, as described above, is used in the method 100.

Referring also to FIGS. 4 to 5, the method 100 is described in detail below:

In step 102, the laser beam L is generated and directed to the imaginary reference surface S where the imaginary reference surface S intersects the imaginary normal T. An incident angle a is defined by the laser beam L and the imaginary normal T.

In step 104, the orientation of the base 30 is adjusted by the adjustment member 12. In the illustrated embodiment, when one of the plane regions 320 is substantially coplanar with the imaginary reference surface S and the imaginary normal T passes through such plane region 320, the plane region 320 reflects the laser beam L to the photo sensor 14, as shown in FIG. 4. A reflection angle β is defined between the reflected laser beam L and the imaginary normal T. When the plane region 320 is correctly oriented, the incident angle a is equal to the reflection angle 3.

In step 106, the reflected laser beam L is received by the photo sensor 14. Thus, the photo sensor 14 senses an intensity of the reflected laser beam L, generates a sensing signal, and transmits the sensing signal to the drive member 16.

In step 108, the drive member 16 receives the sensing signal. The pick up element 16B is moved to hold the solid-state light source 20. In the illustrated embodiment, the solid-state light source 20 defines a central axis M, which is preferably coaxial with the processing path P. Thus by moving the pick up element 16B along the processing path P towards the base 30 using the arm 16A, the first surface 200 of the solid-state light source 20 is substantially parallel to the plane region 320 and can be accurately attached to the plane region 320. It is noted that intimate joining between the solid-state light source 20 and the base 30 can be best achieved by attaching the solid-state light source 20 to the base 30 with the central axis M being coaxial with the imaginary normal T, as shown in FIGS. 4 and 5.

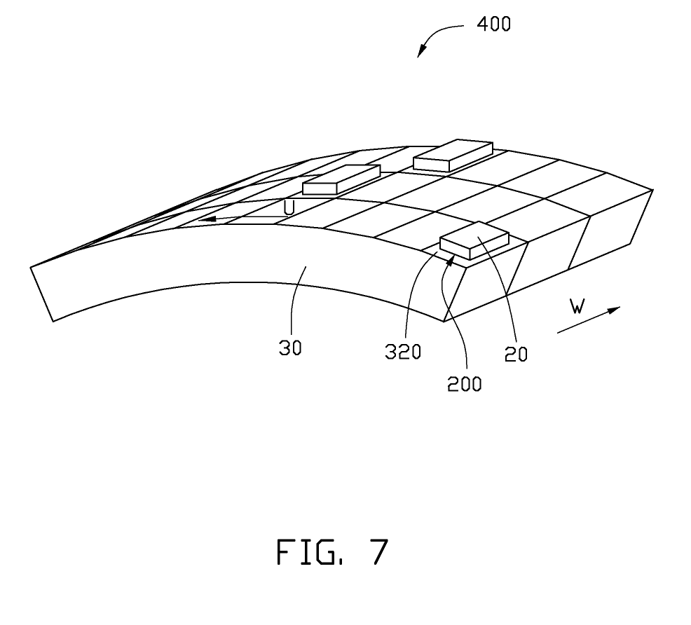

In further or alternative embodiments, a plurality of solid-state light sources 20 can be provided. Each of the solid-state light sources 20 can be attached to a selected one of a plurality of plane regions 320 of the base 30 by applying the method 100 as described above. Thereby, the base 30 together with the solid-state light sources 20 cooperatively form an illumination device 400, as shown in FIG. 7. The illumination device 400 provides a large radiating range.

Another advantage of the illumination device 400 is that each of the solid-state light sources 20 is intimately attached to a corresponding plane region 320. Thus heat from the solid-state light sources 20 can be efficiently transferred to the base 30. The heat can then be dissipated to ambient air. As a result, the brightness and luminous efficiency of the solid-state light sources 20 can be maintained, even when the illumination device 400 operates for a long period of time. To transfer and dissipate heat from the solid-state light sources 20 better, the base 30 may for example be made of metallic material with high thermal conductivity, such as aluminum, copper, aluminum-copper alloy, or another suitable metallic material.

Each solid-state light source 20 can be attached to the base 30 directly. In one embodiment, a eutectic process can be applied when the solid-state light source 20 is attached to the base 30. For instance, the eutectic process is applied by adhering the material of the plane region 320 with the material of the first surface 200 within an ultrasonic field and high temperature environment. Such adhesion can be achieved by melting, bonding, fusing, etc. In alternative embodiments, the solid-state light source 20 may be attached to the base 30 through an adhesive layer (not shown). The adhesive layer can be coated on either or both of the plane region 320 and the first surface 200, before the solid-state light source 20 is attached to the base 30. The adhesive layer may be made of metallic material selected from the group consisting of gold, tin, and silver; or the adhesive layer may be colloidal silver, or solder paste, or another suitable adhesive material.

The plane regions 320 of the supporting surface 32 may have different surface roughnesses. Steps 102-106 may be repeated over a plurality of cycles in order to select the most suitable plane region (or regions) 320. In one example for selecting the most suitable plane region 320, the control module 18 controls the adjustment member 12 to adjust the orientation of the base 30. For example, the orientation of the base 30 can be adjusted in such a manner that a plurality of plane regions 320 in a predetermined path along the base 30 reflect the laser beam L in sequence. In each cycle, a corresponding plane region 320 in the predetermined path reflects the laser beam L to the photo sensor 14. The photo sensor 14 senses the intensity of the reflected laser beam L, generates a sensing signal, and transmits the sensing signal to the control module 18. The control module 18 stores all the intensities of the reflected laser beam L reflected by the different plane regions 320. Then the control module 18 compares all the intensities of the reflected laser beam L, and (in one example) selects the plane region 320 that reflects the laser beam L with the largest intensity as being the most suitable plane region 320. Subsequently, the control module 18 controls the adjustment member 12 to adjust the orientation of the base 30. Thereby, the most suitable plane region 320 is positioned to be substantially coplanar with the imaginary reference surface S. In addition, the control module 18 controls the drive member 16 to hold and move the solid-state light source 20 toward the base 30. Thus the solid-state light source 20 is secured to the most suitable plane region 320.

The predetermined path can be preset as needed. For example, a predetermined path U as illustrated in FIG. 7 is preset to be generally perpendicular to the extending direction W. Initially, the predetermined path U passes through nine plane regions 320 in a same row of the plane regions 320. The most suitable plane region 320 in that row of plane regions 320 is then selected. Such suitable plane region 320 may advantageously have a roughness average (Rₐ) of less than 150 nanometers (nm), or have a Root Mean Square roughness (RMS roughness) of less than 30 nm. The predetermined path U is then translated to pass through nine plane regions 320 in a next same row of the plane regions 320, and the above-described procedure is repeated for that row. In this way, all the rows of the plane regions 320 can be surveyed for selecting of the most suitable plane region 320 in each row.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. An apparatus for securing a solid-state light source on a light source base, the solid-state light source having a light source surface and a central axis perpendicular to the light source surface, the light source base having a supporting surface, the supporting surface being comprised of a plurality of substantially plane regions, the apparatus comprising:
a laser emitter configured for generating a laser beam directed to an imaginary reference surface having an imaginary normal, with an incident angle being defined between the laser beam and the imaginary normal;
an adjustment member configured for adjusting an orientation of the light source base to position a selected plane region of the supporting surface substantially coplanar with the imaginary reference surface with the imaginary normal passing through the selected plane region, whereby the selected plane region reflects the laser beam;
a photo sensor configured for sensing an intensity of the laser beam reflected from the selected plane region and generating a sensing signal; and
a drive member configured for moving the solid-state light source toward the light source base based on the sensing signal, with the central axis of the solid-state light source being substantially coaxial with the imaginary normal.

2. The apparatus of claim 1, further comprising:
a control module communicatively coupled to the adjustment member and the photo sensor, the control module configured for controlling the adjustment member to adjust the orientation of the light source base in such a manner that a plurality of plane regions in a predetermined path along the light source base reflect the laser beam to the photo sensor in sequence, and for selecting one of the plane regions as most suitable for attaching the solid-state light source thereon according to the intensities of the laser beam reflected by the different plane regions.

3. The apparatus of claim 1, wherein the adjustment member comprises a movable base, and a clamp coupled to the movable base, and the clamp is configured for clamping the light source base.

4. The apparatus of claim 1, wherein the drive member comprises a movable arm and a pick up element coupled to the arm, and the pick up element is configured for holding the solid-state light source.

5. The apparatus of claim 4, wherein the pick up element comprises a suction cup.

6. The apparatus of claim 1, wherein the drive member defines a processing path substantially coaxial with the imaginary normal, and the drive member moves the solid-state light source toward the light source base along the processing path.

7. A method for securing a solid-state light source on a base, the solid-state light source having a light source surface and a central axis perpendicular to the light source surface, the base having a supporting surface, the supporting surface being comprised of a plurality of substantially plane regions, the method comprising:
generating a laser beam directed to an imaginary reference surface having an imaginary normal, with an incident angle being defined between the laser beam and the imaginary normal;
adjusting an orientation of the base to position a selected plane region of the supporting surface substantially coplanar with the imaginary reference surface, with the imaginary normal passing through the selected plane region, whereby the selected plane region reflects the laser beam;
sensing an intensity of the laser beam reflected from the selected plane region and generating a sensing signal; and
moving the solid-state light source toward the base based on the sensing signal until the light source surface of the solid-state light source is attached to the plane region, with the central axis of the solid-state light source being substantially coaxial with the imaginary normal.

8. The method of claim 7, wherein the solid-state light source is moved toward the base along a processing path substantially coaxial with the imaginary normal.

9. The method of claim 7, further comprising coating an adhesive layer on at least one of the selected plane region and the light source surface of the solid-state light source before the solid-state light source is attached to the base.

10. A method for securing a solid-state light source on a base, the solid-state light source having a light source surface and a central axis perpendicular to the light source surface, the base having a supporting surface, the supporting surface being comprised of a plurality of substantially plane regions, the method comprising:
generating a laser beam directed to an imaginary reference surface having an imaginary normal, with an incident angle being defined between the laser beam and the imaginary normal;
adjusting an orientation of the base to position each of a plurality of different plane regions substantially coplanar with the imaginary reference surface in turn in a predetermined sequence, wherein when each plane region is substantially coplanar with the imaginary reference surface, the imaginary normal passes through that plane region;
sensing intensities of the laser beam reflected from the different plane regions, and generating a plurality of sensing signals;
selecting a most suitable plane region for attaching of the solid-state light source thereon according to the sensing signals; and
moving the solid-state light source toward the base until the light source surface of the solid-state light source is attached to the selected plane region, with the central axis of the solid-state light source being substantially coaxial with the imaginary normal.

11. The method of claim 10, wherein the solid-state light source is moved toward the base along a processing path substantially coaxial with the imaginary normal.

12. The method of claim 10, further comprising coating an adhesive layer on at least one of the selected plane region and the light source surface of the solid-state light source before the solid-state light source is attached to the base.
